(19) United States
(12) Patent Application Publication
(10) Pub. No.: US 2025/0231129 A1
(43) Pub. Date: Jul. 17, 2025

(54) E-BEAM OPTIMIZATION FOR OVERLAY MEASUREMENT OF BURIED FEATURES

(71) Applicant: ASML Netherlands B.V., Veldhoven (NL)

(72) Inventors: Benoit Herve GAURY, Eindhoven (NL); Thomas Jarik HUISMAN, Eindhoven (NL); Antoine Gaston Marie KIERS, Veldhoven (NL); Guangqing CHEN, Fremont, CA (US)

(73) Assignee: ASML Netherlands B.V., Veldhoven (NL)

(21) Appl. No.: 18/853,983

(22) PCT Filed: Mar. 6, 2023
(86) PCT No.: PCT/EP2023/055565

§ 371 Date: Oct. 3, 2024

Related U.S. Application Data
(60) Provisional application No. 63/327,337, filed on Apr. 4, 2022.

(51) Int. Cl. G01N 23/2251; H01J 37/28

(52) U.S. Cl. CPC G01N 23/2251; H01J 37/28; G01N 2223/6116; H01J 2237/24475; H01J 2237/24535; H01J 2237/2817

(57) ABSTRACT

Systems, non-transitory computer readable medium, and methods for determining one or more parameters used by an e-beam for an overlay measurement are disclosed. In some embodiments, the method comprises determining an acquisition time for the overlay measurement of a wafer stack based on a plurality of characteristics of the wafer stack and a plurality of backscattered electron (BSE) yields detected at a plurality of features on the wafer stack. The method also comprises determining the one or more parameters including a landing energy of the e-beam based on optimization of the acquisition time for the overlay measurement.

### CROSS-REFERENCE TO RELATED APPLICATIONS

This application claims priority of U.S. application 63/327,337 which was filed on 4 Apr. 2022 and which is incorporated herein in its entirety by reference.

### TECHNICAL FIELD

The embodiments provided herein relate to a system and a method for optimizing e-beam parameters, such as scanning electron microscope (SEM) operating parameters, for measurement of buried features, and more particularly, for improving overlay measurement efficiency.

### BACKGROUND

In manufacturing processes of integrated circuits (ICs), unfinished or finished circuit components are inspected to ensure that they are manufactured according to design and are free of defects. Inspection systems utilizing optical microscopes or charged particle (e.g., electron) beam microscopes, such as a scanning electron microscope (SEM) may be employed. As the physical sizes of IC components continue to shrink, accuracy and yield in defect detection become more important.

In order to monitor one or more steps of the device manufacturing process, such as a lithography process including, e.g., exposure, resist-processing, etching, development, baking, etc., a sample, such as a substrate patterned by the device manufacturing process or a patterning device used therein, may be inspected, in which one or more parameters of the sample may be measured. Overlay measurement is an important control metric for semiconductor devices manufacturing. Inspection may find pattern defects, such as error in positioning, failed connection, failed separation, or uninvited particles. Inspection of substrates and patterning devices used in a device manufacturing process can help to improve the yield. The information obtained from the inspection can be used to identify defects, or to adjust the device manufacturing process.

### SUMMARY

Embodiments of the present disclosure provide methods, apparatuses, and systems for optimizing an SEM operation recipe, including one or more SEM parameters, for overlay measurement.

In some embodiments, a system for determining one or more parameters used by an e-beam for an overlay measurement is provided. The system comprises a controller including circuitry configured to cause the system to perform determining an acquisition time for the overlay measurement of a wafer stack based on a plurality of characteristics of the wafer stack and a plurality of backscattered electron (BSE) yields detected at a plurality of features on the wafer stack; and determining the one or more parameters including a landing energy of the e-beam based on optimization of the acquisition time for the overlay measurement.

In some embodiments, a method of determining one or more parameters used by an e-beam for an overlay measurement is provided. The method comprises determining an acquisition time for the overlay measurement of a wafer stack based on a plurality of characteristics of the wafer stack and a plurality of backscattered electron (BSE) yields detected at a plurality of features on the wafer stack; and determining the one or more parameters including a landing energy of the e-beam based on optimization of the acquisition time for the overlay measurement.

In some embodiments, a non-transitory computer readable medium that stores a set of instructions that is executable by at least one processor of a system to cause the system to perform a method of determining one or more parameters used by an e-beam for an overlay measurement. The method comprises determining an acquisition time for the overlay measurement of a wafer stack based on a plurality of characteristics of the wafer stack and a plurality of backscattered electron (BSE) yields detected at a plurality of features on the wafer stack; and determining the one or more parameters including a landing energy of the e-beam based on optimization of the acquisition time for the overlay measurement.

In some embodiments, a system for determining one or more parameters used by an e-beam for an overlay measurement is provided. The system comprises a controller including circuitry configured to cause the system to perform: determining a plurality of backscattered electron (BSE) yields detected at a plurality of features on a wafer stack, wherein the BSE yields are determined by a first group of wafer stack parameters of the wafer stack and a second group of material properties and e-beam parameters; optimizing an acquisition time for the overlay measurement of the wafer stack, the acquisition time determined based on the first group of wafer stack parameters and the plurality of backscattered electron (BSE) yields; and determining the one or more parameters including a landing energy of the e-beam based on the optimized acquisition time for the overlay measurement.

In some embodiments, a non-transitory computer readable medium that stores a set of instructions that is executable by at least one processor of a system to cause the system to perform a method of determining one or more parameters used by an e-beam for an overlay measurement. The method comprises determining a plurality of backscattered electron (BSE) yields detected at a plurality of features on a wafer stack, wherein the BSE yields are determined by a first group of wafer stack parameters of the wafer stack and a second group of material properties and e-beam parameters; optimizing an acquisition time for the overlay measurement of the wafer stack, the acquisition time determined based on the first group of wafer stack parameters and the plurality of backscattered electron (BSE) yields; and determining the one or more parameters including a landing energy of the e-beam based on the optimized acquisition time for the overlay measurement.

In some embodiments, a method of determining one or more parameters used by an e-beam for an overlay measurement is provided. The method comprises determining a plurality of backscattered electron (BSE) yields detected at a plurality of features on a wafer stack, wherein the BSE yields are determined by a first group of wafer stack parameters of the wafer stack and a second group of material properties and e-beam parameters; optimizing an acquisition time for the overlay measurement of the wafer stack, the acquisition time determined based on the first group of wafer stack parameters and the plurality of backscattered electron (BSE) yields; and determining the one or more parameters including a landing energy of the e-beam based on the optimized acquisition time for the overlay measurement.

Other advantages of the embodiments of the present disclosure will become apparent from the following description taken in conjunction with the accompanying drawings wherein are set forth, by way of illustration and example, certain embodiments of the present invention.

### BRIEF DESCRIPTION OF FIGURES

FIG. 1 illustrates a schematic diagram illustrating an example electron beam inspection (EBI) system, consistent with some embodiments of the present disclosure.

FIG. 2 illustrates a schematic diagram illustrating an example electron beam tool that can be a part of the electron beam inspection system of FIG. 1, consistent with some embodiments of the present disclosure.

FIG. 3 is a block diagram of an example system for performing optimized overlay measurement, consistent with some embodiments of the present disclosure.

FIG. 4 is a schematic diagram illustrating a process of SEM parameters optimization for overlay measurement, consistent with some embodiments of the present disclosure.

FIG. 5A is a schematic diagram illustrating a cross-sectional view of a wafer including buried gratings in an underlying layer, consistent with some embodiments of the present disclosure.

FIG. 5B is a schematic diagram illustrating a cross-sectional view showing electron beams with different landing energies passing through features on a wafer, consistent with some embodiments of the present disclosure.

FIG. 6A is a schematic diagram illustrating an example showing the relationships between optimal beam currents and certain pitch for the buried gratings in FIG. 5A, consistent with some embodiments of the present disclosure.

FIG. 6B is a schematic diagram illustrating an example of a throughput gain corresponding obtained by selecting the optimal landing energy for a certain wafer stack, consistent with some embodiments of the present disclosure.

FIG. 7 is a process flowchart representing an example method for determining one or more parameters used by an e-beam for an overlay measurement, in accordance with some embodiments of the present disclosure.

### DETAILED DESCRIPTION

Reference will now be made in detail to exemplary embodiments, examples of which are illustrated in the accompanying drawings. The following description refers to the accompanying drawings in which the same numbers in different drawings represent the same or similar elements unless otherwise represented. The implementations set forth in the following description of exemplary embodiments do not represent all implementations. Instead, they are merely examples of apparatuses and methods consistent with aspects related to the disclosed embodiments as recited in the appended claims. For example, although some embodiments are described in the context of utilizing electron beams, the disclosure is not so limited. Other types of charged particle beams may be similarly applied. Furthermore, other imaging systems may be used, such as optical imaging, photo detection, x-ray detection, etc.

Electronic devices are constructed of circuits formed on a piece of silicon called a substrate. Many circuits may be formed together on the same piece of silicon and are called integrated circuits or ICs. The size of these circuits has decreased dramatically so that many more of them can fit on the substrate. For example, an IC chip in a smart phone can be as small as a thumbnail and yet may include over 2 billion transistors, the size of each transistor being less than 1/1000th the size of a human hair.

Making these extremely small ICs is a complex, time-consuming, and expensive process, often involving hundreds of individual steps. Errors in even one step (e.g., in design or patterning) have the potential to result in defects in the finished IC rendering it useless. Thus, one goal of the manufacturing process is to avoid such defects to maximize the number of functional ICs made in the process, that is, to improve the overall yield of the process.

One component of improving yield is monitoring the chip making process to ensure that it is producing a sufficient number of functional integrated circuits. One way to monitor the process is to inspect the chip circuit structures at various stages of their formation. Inspection can be carried out using a scanning electron microscope (SEM). An SEM can be used to image these extremely small structures, in effect, taking a “picture” of the structures. The image can be used to determine if the structure was formed properly and also if it was formed in the proper location. If the structure is defective, then the process can be adjusted so the defect is less likely to recur. Defects may be generated during various stages of semiconductor processing. Buried features are features buried under a surface of a sample, and can include a layer, a line feature, a void, a dot, or in any other suitable pattern(s), and can include defects after lithography patterning or etching. Therefore, it is important to inspect the buried features and identify potential defects accurately and efficiently as early as possible.

A charged particle beam (e.g., electron beam, or e-beam) microscope, such as a scanning electron microscope (SEM) or a transmission electron microscope (TEM) can serve as a practicable tool for inspecting IC components. Different technologies exist for performing overlay measurements, including optical overlay metrology, X-ray overlay metrology, or SEM, etc. Optical metrology may not be sufficient for the up-to-date small scale features. Low voltage SEM based technology may be suitable after metal filling and polishing, but not after development stage. High-voltage SEM can be used for overlay measurement of buried or partially buried features. For example, landing energies in the range of several tens of kilo electron volts may enable electrons to penetrate and scatter back from features buried several hundreds of nanometers deep. However, finding the optimal SEM settings, such as the optimal landing energy or optimal beam current, may be challenging.

Currently, finding the optimal SEM parameters are based on trial and error, or drawing from experience. However, such methodology often results in poor measurement quality and low throughput. While landing energy and beam current are critical to get high throughput, there is no clear understanding of the relationship between these parameters and the time required for overlay measurement with a given precision on a given stack. Accordingly, there is a need for a methodology, such as an automated methodology, to obtain SEM recipe for optimized overlay measurement with improved efficiency.

Relative dimensions of components in drawings may be exaggerated for clarity. Within the following description of drawings, the same or like reference numbers refer to the same or like components or entities, and only the differences with respect to the individual embodiments are described. As used herein, unless specifically stated otherwise, the term “or” encompasses all possible combinations, except where infeasible. For example, if it is stated that a component may include A or B, then, unless specifically stated otherwise or infeasible, the component may include A, or B, or A and B. As a second example, if it is stated that a component may include A, B, or C, then, unless specifically stated otherwise or infeasible, the component may include A, or B, or C, or A and B, or A and C, or B and C, or A and B and C.

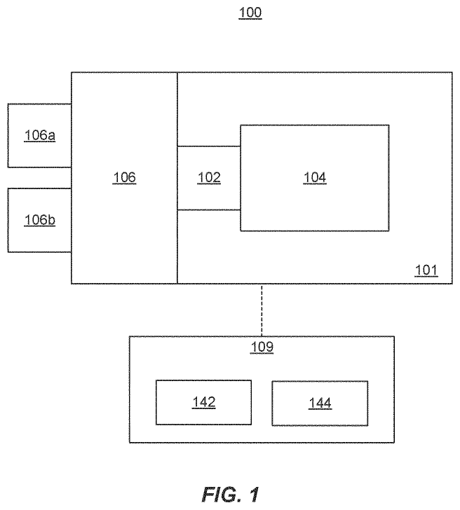

FIG. 1 illustrates an exemplary electron beam inspection (EBI) system 100 consistent with some embodiments of the present disclosure. EBI system 100 may be used for imaging. As shown in FIG. 1, EBI system 100 includes a main chamber 101, a load/lock chamber 102, an electron beam tool 104, and an equipment front end module (EFEM) 106. Electron beam tool 104 is located within main chamber 101. EFEM 106 includes a first loading port 106a and a second loading port 106b. EFEM 106 may include additional loading port(s). First loading port 106a and second loading port 106b receive wafer front opening unified pods (FOUPs) that contain wafers (e.g., semiconductor wafers or wafers made of other material(s)) or samples to be inspected (wafers and samples may be used interchangeably, or collectively referred to as “wafers” herein). A “lot” is a plurality of wafers that may be loaded for processing as a batch.

One or more robotic arms (not shown) in EFEM 106 may transport the wafers to load/lock chamber 102. Load/lock chamber 102 is connected to a load/lock vacuum pump system (not shown) which removes gas molecules in load/lock chamber 102 to reach a first pressure below the atmospheric pressure. After reaching the first pressure, one or more robotic arms (not shown) may transport the wafer from load/lock chamber 102 to main chamber 101. Main chamber 101 is connected to a main chamber vacuum pump system (not shown) which removes gas molecules in main chamber 101 to reach a second pressure below the first pressure. After reaching the second pressure, the wafer is subject to inspection by electron beam tool 104. Electron beam tool 104 may be a single-beam system or a multi-beam system. It is appreciated that the system and method disclosed herein can apply to both single-beam system and multi-beam system.

A controller 109 is electronically connected to electron beam tool 104. Controller 109 may be a computer configured to execute various controls of EBI system 100. Controller 109 may also include processing circuitry configured to execute various signal and image processing functions, or determine or adjust parameter settings of EBI system 100. In some embodiments, controller 109 may be separate and independent from EBI system 100. For example, controller 109 may be a computer communicatively coupled to EBI system 100. In some embodiments, while controller 109 is shown in FIG. 1 as being outside of the structure that includes main chamber 101, load/lock chamber 102, and EFEM 106, it is appreciated that controller 109 may be a part of the structure.

In some embodiments, controller 109 may include one or more processors 142. A processor may be a generic or specific electronic device capable of manipulating or processing information. For example, the processor may include any combination of any number of a central processing unit (or “CPU”), a graphics processing unit (or “GPU”), an optical processor, a programmable logic controllers, a microcontroller, a microprocessor, a digital signal processor, an intellectual property (IP) core, a Programmable Logic Array (PLA), a Programmable Array Logic (PAL), a Generic Array Logic (GAL), a Complex Programmable Logic Device (CPLD), a Field-Programmable Gate Array (FPGA), a System On Chip (SoC), an Application-Specific Integrated Circuit (ASIC), and any type circuit capable of data processing. The processor may also be a virtual processor that includes one or more processors distributed across multiple machines or devices coupled via a network.

In some embodiments, controller 109 may further include one or more memories 144. A memory may be a generic or specific electronic device capable of storing codes and data accessible by the processor (e.g., via a bus). For example, the memory may include any combination of any number of a random-access memory (RAM), a read-only memory (ROM), an optical disc, a magnetic disk, a hard drive, a solid-state drive, a flash drive, a security digital (SD) card, a memory stick, a compact flash (CF) card, or any type of storage device. The codes may include an operating system (OS) and one or more application programs (or “apps”) for specific tasks. The memory may also be a virtual memory that includes one or more memories distributed across multiple machines or devices coupled via a network.

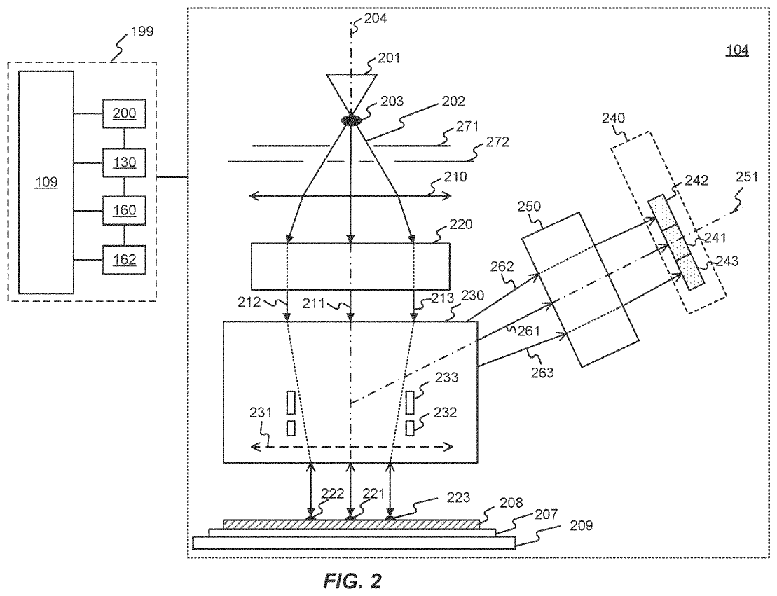

Reference is now made to FIG. 2, which is a schematic diagram illustrating an exemplary electron beam tool 104 including a multi-beam inspection tool that is part of the EBI system 100 of FIG. 1, consistent with some embodiments of the present disclosure. Multi-beam electron beam tool 104 (also referred to herein as apparatus 104) comprises an electron source 201, a Coulomb aperture plate (or “gun aperture plate”) 271, a condenser lens 210, a source conversion unit 220, a primary projection system 230, a motorized stage 209, and a sample holder 207 supported by motorized stage 209 to hold a wafer 208 to be inspected. Multi-beam electron beam tool 104 may further comprise a secondary projection system 250 and an electron detection device 240. Primary projection system 230 may comprise an objective lens 231. Electron detection device 240 may comprise a plurality of detection elements 241, 242, and 243. A beam separator 233 and a deflection scanning unit 232 may be positioned inside primary projection system 230.

Electron source 201, Coulomb aperture plate 271, condenser lens 210, source conversion unit 220, beam separator 233, deflection scanning unit 232, and primary projection system 230 may be aligned with a primary optical axis 204 of apparatus 104. Secondary projection system 250 and electron detection device 240 may be aligned with a secondary optical axis 251 of apparatus 104.

Electron source 201 may comprise a cathode (not shown) and an extractor or anode (not shown), in which, during operation, electron source 201 is configured to emit primary electrons from the cathode and the primary electrons are extracted or accelerated by the extractor and/or the anode to form a primary electron beam 202 that form a primary beam crossover (virtual or real) 203. Primary electron beam 202 may be visualized as being emitted from primary beam crossover 203.

Source conversion unit 220 may comprise an image-forming element array (not shown), an aberration compensator array (not shown), a beam-limit aperture array (not shown), and a pre-bending micro-deflector array (not shown). In some embodiments, the pre-bending micro-deflector array deflects a plurality of primary beamlets 211, 212, 213 of primary electron beam 202 to normally enter the beam-limit aperture array, the image-forming element array, and an aberration compensator array. In some embodiment, condenser lens 210 is designed to focus primary electron beam 202 to become a parallel beam and be normally incident onto source conversion unit 220. The image-forming element array may comprise a plurality of micro-deflectors or micro-lenses to influence the plurality of primary beamlets 211, 212, 213 of primary electron beam 202 and to form a plurality of parallel images (virtual or real) of primary beam crossover 203, one for each of the primary beamlets 211, 212, and 213. In some embodiments, the aberration compensator array may comprise a field curvature compensator array (not shown) and an astigmatism compensator array (not shown). The field curvature compensator array may comprise a plurality of micro-lenses to compensate field curvature aberrations of the primary beamlets 211, 212, and 213. The astigmatism compensator array may comprise a plurality of micro-stigmators to compensate astigmatism aberrations of the primary beamlets 211, 212, and 213. The beam-limit aperture array may be configured to limit diameters of individual primary beamlets 211, 212, and 213. FIG. 2 shows three primary beamlets 211, 212, and 213 as an example, and it is appreciated that source conversion unit 220 may be configured to form any number of primary beamlets. Controller 109 may be connected to various parts of EBI system 100 of FIG. 1, such as source conversion unit 220, electron detection device 240, primary projection system 230, or motorized stage 209. In some embodiments, as explained in further details below, controller 109 may perform various image and signal processing functions. Controller 109 may also generate various control signals to control operations of one or more components of the charged particle beam inspection system.

Condenser lens 210 is configured to focus primary electron beam 202. Condenser lens 210 may further be configured to adjust electric currents of primary beamlets 211, 212, and 213 downstream of source conversion unit 220 by varying the focusing power of condenser lens 210. Alternatively, the electric currents may be changed by altering the radial sizes of beam-limit apertures within the beam-limit aperture array corresponding to the individual primary beamlets. The electric currents may be changed by both altering the radial sizes of beam-limit apertures and the focusing power of condenser lens 210. Condenser lens 210 may be an adjustable condenser lens that may be configured so that the position of its first principle plane is movable. The adjustable condenser lens may be configured to be magnetic, which may result in off-axis beamlets 212 and 213 illuminating source conversion unit 220 with rotation angles. The rotation angles change with the focusing power or the position of the first principal plane of the adjustable condenser lens. Condenser lens 210 may be an anti-rotation condenser lens that may be configured to keep the rotation angles unchanged while the focusing power of condenser lens 210 is changed. In some embodiments, condenser lens 210 may be an adjustable anti-rotation condenser lens, in which the rotation angles do not change when its focusing power and the position of its first principal plane are varied.

Objective lens 231 may be configured to focus beamlets 211, 212, and 213 onto wafer 208 for inspection and may form, in the current embodiments, three probe spots 221, 222, and 223 on the surface of wafer 208. Coulomb aperture plate 271, in operation, is configured to block off peripheral electrons of primary electron beam 202 to reduce Coulomb effect. The Coulomb effect may enlarge the size of each of probe spots 221, 222, and 223 of primary beamlets 211, 212, 213, and therefore deteriorate inspection resolution.

Beam separator 233 may, for example, be a Wien filter comprising an electrostatic deflector generating an electrostatic dipole field and a magnetic dipole field (not shown in FIG. 2). In operation, beam separator 233 may be configured to exert an electrostatic force by electrostatic dipole field on individual electrons of primary beamlets 211, 212, and 213. The electrostatic force is equal in magnitude but opposite in direction to the magnetic force exerted by magnetic dipole field of beam separator 233 on the individual electrons. Primary beamlets 211, 212, and 213 may therefore pass at least substantially straight through beam separator 233 with at least substantially zero deflection angles.

Deflection scanning unit 232, in operation, is configured to deflect primary beamlets 211, 212, and 213 to scan probe spots 221, 222, and 223 across individual scanning areas in a section of the surface of wafer 208. In response to incidence of primary beamlets 211, 212, and 213 or probe spots 221, 222, and 223 on wafer 208, electrons emerge from wafer 208 and generate three secondary electron beams 261, 262, and 263. Each of secondary electron beams 261, 262, and 263 typically comprise secondary electrons (having electron energy≤50 eV) and backscattered electrons (having electron energy between 50 e V and the landing energy of primary beamlets 211, 212, and 213). Beam separator 233 is configured to deflect secondary electron beams 261, 262, and 263 towards secondary projection system 250. Secondary projection system 250 subsequently focuses secondary electron beams 261, 262, and 263 onto detection elements 241, 242, and 243 of electron detection device 240. Detection elements 241, 242, and 243 are arranged to detect corresponding secondary electron beams 261, 262, and 263 and generate corresponding signals (e.g., voltage, current, or the like) which are sent to controller 109 or a signal processing system (not shown), e.g., to reconstruct images of the corresponding scanned areas on or underneath the surface area of wafer 208.

In some embodiments, detection elements 241, 242, and 243 detect corresponding secondary electron beams 261, 262, and 263, respectively, and generate corresponding intensity signal outputs (e.g., voltage, current, or the like) to controller 109. In some embodiments, each detection element 241, 242, and 243 may comprise one or more pixels. The intensity signal output of a detection element may be a sum of signals generated by all the pixels within the detection element.

In some embodiments, when electrons of primary electron beam 202 are projected onto a surface of wafer 208 (e.g., probe spots 221, 222, and 223), the electrons of primary electron beam 202 may penetrate the surface of wafer 208 for a certain depth, interacting with particles of wafer 208 or particles of buried features under the surface of wafer 208. Some electrons of primary electron beam 202 may elastically interact with (e.g., in the form of elastic scattering or collision) the materials of wafer 208 or the buried features, and may be reflected or recoiled out of the surface of wafer 208. An elastic interaction conserves the total kinetic energies of the bodies (e.g., electrons of primary electron beam 202) of the interaction, in which the kinetic energy of the interacting bodies does not convert to other forms of energy (e.g., heat, electromagnetic energy, or the like). Such reflected electrons generated from elastic interaction may be referred to as backscattered electrons (BSEs). Some electrons of primary electron beam 202 may inelastically interact with (e.g., in the form of inelastic scattering or collision) the materials of wafer 208 or the buried features. An inelastic interaction does not conserve the total kinetic energies of the bodies of the interaction, in which some or all of the kinetic energy of the interacting bodies convert to other forms of energy. For example, through the inelastic interaction, the kinetic energy of some electrons of primary electron beam 202 may cause electron excitation and transition of atoms of the materials. Such inelastic interaction may also generate electrons exiting the surface of wafer 208, which may be referred to as secondary electrons (SEs). Yield or emission rates of BSEs and SEs depend on, e.g., the material under inspection and the landing energy of the electrons of primary electron beam 202 landing on the surface of the material, among others. The energy of the electrons of primary electron beam 202 may be imparted in part by its acceleration voltage (e.g., the acceleration voltage between the anode and cathode of charged-particle source 201 in FIG. 2). The quantity of BSEs and SEs may be more or fewer (or even the same) than the injected electrons of primary electron beam 202.

As shown in FIG. 2, an e-beam optimization system 199 (or “system 199”) may be provided by or communicatively coupled to system 104. For example, system 199 may include an optimization model generator 200, a storage 130, an input parameters acquirer 160 (or “an input acquirer 160”), an output generator 162, and controller 109 that are communicatively coupled to each other. In some embodiments, optimization model generator 200, storage 130, input acquirer 160, or output generator 162 may be integrated as a module of controller 109 or system 199, or include a component that can be implemented in controller 109 or system 199. In some embodiments, system 199 or controller 109 may obtain one or more input parameters as disclosed herein, including but not limited to parameters of wafer stacks, parameter settings of SEM, or parameters related to overlay precision. In some embodiments, system 199 or controller 109 may generate or control one or more parameters of apparatus 104, such as landing energy of primary beam, or electrical current of primary beams that may be used for obtaining optimized acquisition time for overlay measurement as disclosed herein.

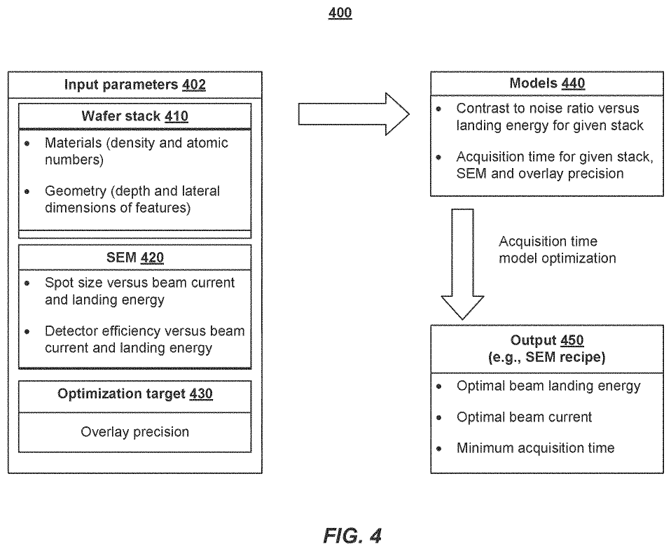

Optimization model generator 200 may comprise one or more processors. For example, optimization model generator 200 may comprise a computer, server, mainframe host, terminals, personal computer, any kind of mobile computing devices, and the like, or a combination thereof. Optimization model generator 200 may be communicatively coupled to apparatus 104 through a medium such as an electrical conductor, optical fiber cable, portable storage media, IR, Bluetooth, internet, wireless network, wireless radio, among others, or a combination thereof. Optimization model generator 200 may generate one or more models that can be used to optimize SEM parameter(s) for overlay measurement of various buried features on wafer 208. In some embodiments, the generated models correspond to different types of buried features of wafer 208. Generated models may be stored in storage 130. In some embodiments, optimization model generator 200 may be configured to provide, in response to a user selection or via an automatic selection, a model that is suitable for the targeted buried feature, e.g., a buried grating on wafer 208 (e.g., FIG. 4).

In some embodiments, controller 109 may include measurement circuitries (e.g., analog-to-digital converters) to obtain a distribution of the detected secondary electrons. The electron distribution data collected during a detection time window, in combination with corresponding scan path data of each of primary beamlets 211, 212, and 213 incident on the wafer surface, can be used to reconstruct images of the wafer structures under inspection. The reconstructed images can be used to reveal various features of the internal or external structures of wafer 208, and thereby can be used to reveal any defects that may exist in the wafer.

Input acquirer 160 or output generator 162 may comprise one or more processors. For example, input acquirer 160 or output generator 162 may comprise a computer, server, mainframe host, terminals, personal computer, any kind of mobile computing devices, and the like, or a combination thereof. Input parameters acquirer 160 or output generator 162 may be communicatively coupled to one or more components of apparatus 104 or system 100 through a medium such as an electric conductor, optical fiber cable, portable storage media, IR, Bluetooth, internet, wireless network, wireless radio, or a combination thereof. In some embodiments, input parameters acquirer 160 may receive information about one or more input parameters as discussed with reference to FIG. 4. In some embodiments, output generator 162 may generate output SEM recipe, including one or more SEM parameters such as primary beam landing energy, primary beam current, as input parameters to apparatus 104.

Storage 130 may be a storage medium such as a hard disk, random access memory (RAM), cloud storage, other types of computer readable memory, and the like. Storage 130 may be coupled with optimization model generator 200, input acquirer 160, or output generator 162, and may be used for saving generated models, various parameter used for generating the models, and parameters used for determining the output SEM recipe, such as wafer stack parameters, and SEM parameters such as hardware settings as disclosed herein.

In some embodiments, controller 109 may be electronically connected to electron beam tool 104. As disclosed herein, controller 109 may be a computer configured to execute various controls of electron beam tool 104. In some embodiments, optimization model generator 200, input acquirer 160, output generator 162, storage 130, and controller 109 may be integrated together as one control unit.

Although FIG. 2 shows that electron beam tool 104 uses three primary electron beams, it is appreciated that electron beam tool 104 may use any suitable number of primary electron beams. The present disclosure does not limit the number of primary electron beams used in electron beam tool 104. Compared with a single charged-particle beam imaging system (“single-beam system”), a multiple charged-particle beam imaging system (“multi-beam system”) may be designed to optimize throughput for different scan modes. Embodiments of this disclosure provide a multi-beam system with the capability of optimizing throughput for different scan modes by using beam arrays with different geometries. adapting to different throughputs and resolution requirements.

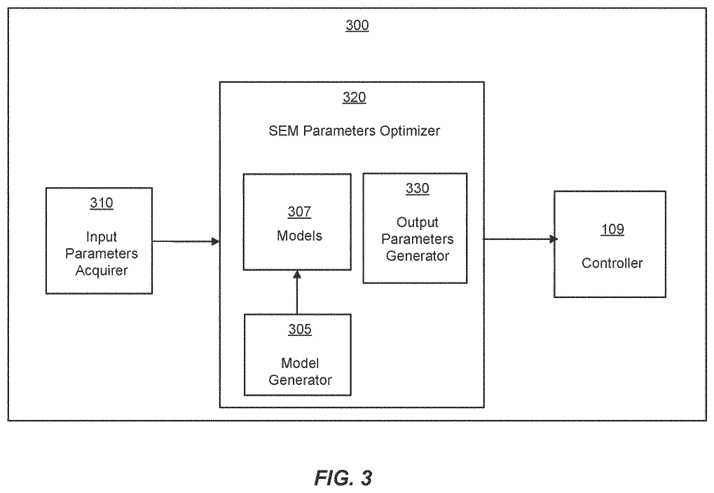

FIG. 3 is a block diagram of an example system 300 for performing optimized overlay measurement, consistent with some embodiments of the present disclosure. In some embodiments, system 300 includes an input parameter acquirer 310, a model generator 305 configured to generate models 307 used by an SEM parameters optimizer 320, an output parameters generator 330 for outputting SEM parameters for the optimized SEM recipe (e.g., optimized landing energy, optimized beam current, etc.).

It is appreciated that system 300 may include one or more components or modules that are integrated as parts of a charged-particle beam inspection system (e.g., electron beam inspection system 100 of FIG. 1). System 300 may also include one or more components or modules separate from and communicatively coupled to the charged-particle beam inspection system. System 300 may comprise one or more processors and storage memories. For example, system 300 may comprise a computer, server, mainframe host, terminals, personal computer, any kind of mobile computing devices, and the like, or a combination thereof. In some embodiments, system 300 may include one or more components, e.g., software modules, hardware modules, or combinations thereof, that can be implemented in controller 109 or system 199 as disclosed herein.

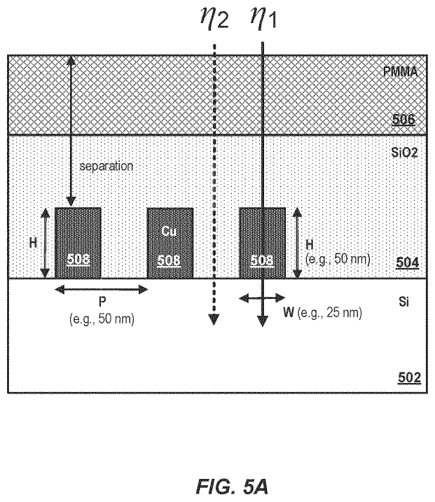

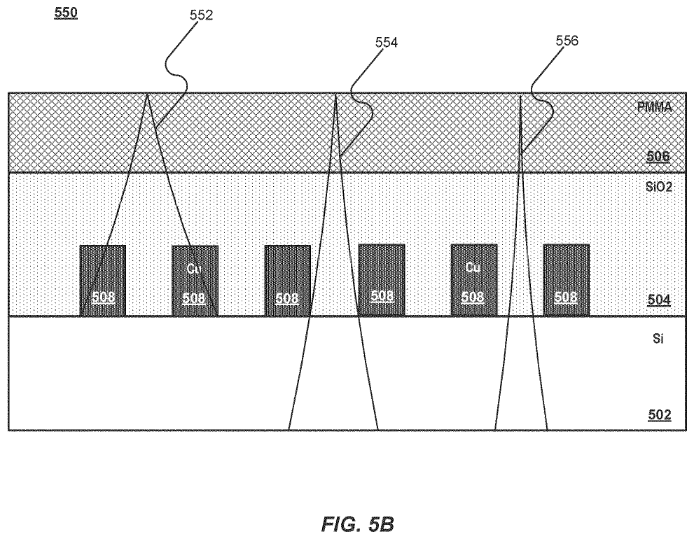

In some embodiments as shown in FIG. 3, system 300 includes input parameters acquirer 310. Input parameters acquirer 310 may be configured to obtain input parameters, e.g., wafer stack parameters, SEM parameters, or predetermined optimization settings, as shown in FIG. 5A, to be processed by system 300. In some embodiments, input parameters acquirer 310 can be substantially similar to input acquirer 160 in FIG. 2. In some embodiments, input parameters acquirer 310 may be different from input acquirer 160. For example, input parameters acquirer 310 may be included or implemented in a computing device separate from the charged-particle beam inspection system.

In some embodiments, system 300 may include model generator 305 configured to generate one or more models 307 to be used by SEM parameters optimizer 320 for determining optimized SEM recipe in accordance with the various features in the wafer. In some embodiments, model generator 305 generates models 307 for providing SEM parameters, such as landing energy or beam current, to minimize the measurement time required for overlay measurement to maintain a certain precision. In some embodiments, model generator 305 can fit collected data points from overlay measurements (e.g., such as BSE yields, and containing both signals and noise) of different locations on the wafer, to a true model (e.g., without noise) using a least squares regression analysis. The uncertainty can be calculated, and the standard deviation of the uncertainty can be used for determining the optimized acquisition time at a certain overlay precision. The optimized acquisition time at the certain overlay precision can be used for determining the related SEM parameters, such as landing energy. In some embodiments, the generated models 307 can include an analytical model, or a Monte Carlo model, or any other suitable type of model.

In some embodiments, SEM parameters optimizer 320 applies a model suitable for a buried feature under measurement, and output parameters generator 330 generates the optimized SEM recipe including output parameters, such as optimal beam landing energy, or optical beam current, to obtain the optimized acquisition time. Controller 109 can apply the optimized SEM parameters to adjust the primary beam landing energy beam current for efficient overlay measurement.

Reference is now made to FIG. 4, which is a schematic diagram illustrating a process 400 of SEM parameters optimization for overlay measurement, consistent with some embodiments of the present disclosure. The process of SEM parameters may be performed by system 300, one or more components of system 100 or apparatus 104. In some embodiments, input parameters 402 include wafer stack parameters 410, such as density, atomic number of the materials in the wafer stack. In some embodiments, the obtained input parameters include feature geometries or dimensions, such as depths, lateral dimensions, heights, pitch, or distances of features in the wafer stack. In some embodiments, the feature geometries may include characteristics information (e.g., shape, dimension, etc.) for various features on different layers, including buried features, that are formed on the wafer. For example, the features may include information associated with various structures, devices, and systems fabricated on the wafer, including but not limited to, substrates, doped regions, poly-gate layers, resistance layers, dielectric layers, metal layers, transistors, processors, memories, metal connections, contacts, vias, lines, gratings, system-on-chips (SoCs), network-on-chips (NoCs), or any other suitable structures.

In some embodiments, input parameters 402 further include SEM parameters 420, such as a relationship between spot size and beam current, or a relationship between spot size and beam landing energy. In some embodiments, SEM parameters 420 may also include a relationship between detector efficiency and beam current, or a relationship between detector efficiency and beam landing energy. In some embodiments, these SEM parameters 420 may be related to hardware settings of the SEM. In some embodiments, input parameters 402 also includes optimization target 430, such as a predetermined overlay precision.

In some embodiments, model generator 305 generates models 440 based on the input parameters 400. Models 440 are related to relationships between contrast to noise ratio and beam landing energy for a given wafer stack. Models 440 are also used for optimizing acquisition time for a given wafer stack, with certain SEM parameters, and at a certain overlay precision.

In some embodiments, output parameters generator 330 generates an optimized SEM recipe including optimized SEM parameters such as primary beam landing energy, primary beam current, to provide minimum or optimized acquisition time for efficient overlay measurement.

In some embodiments, a model is obtained by collecting the data points including both signal and noise from the measurement, and fitting the data points with a true model (without noise) using least squares regression analysis. The fitting process may output fitted parameters (e.g., the output parameters) and an uncertainty. In some embodiments, the uncertainty is expressed in a covariance matrix Q as the output of a least squares fitting of a model to data:

$$Q = {[ {J}^{T} {C}^{- 1} J ]}^{- 1}$$

where J is the Jacobian matrix of the model, and C is the correlation matrix.

In some embodiments, it is assumed that a line scan of N pixels is performed and overlay (OV) is the model (M) parameter, and model generator 305 may apply the Jacobian matrix J as:

$$J = ( \begin{matrix}\frac{\partial M}{\partial OV} ( {x}_{1} , OV ) \\ \frac{\partial M}{\partial OV} ( {x}_{12} , OV ) \\ ⋮ \\ ⋮ \\ \frac{\partial M}{\partial OV} ( {x}_{N} , OV )\end{matrix} )$$

In some embodiments, it is also assumed that the covariance matrix Cis diagonal and containing sample noise. The backscattered (BSE) yield variance at each pixel may be equal to the mean yield, such as Poisson noise. In some embodiments, Gaussian noise may be used for the procedure. In some embodiments, model generator 305 may apply covariance matrix C as:

$$C = ( \begin{matrix}M ( {x}_{1} , OV ) & & \\ & ⋱ & \\ & & M ( {x}_{N} , OV )\end{matrix} )$$

The vector in Jacobian matrix J can be obtained as:

$$\frac{\partial M}{\partial OV} ( {x}_{i} , OV ) ∼ [ M ( {x}_{i} , OV + h ) - M ( {x}_{i} , OV - h ) ] / 2 h$$

In some embodiments, a scalar Q is shown as:

$$Q = {[ {\sum }_{i = 1}^{{N}_{p i x e l s}} \frac{1}{M ( {x}_{i} , OV )} {( \frac{\partial M}{\partial OV} ( {x}_{i} , OV ) )}^{2} ]}^{- 1}$$

In some embodiments, the model M is a function of the number of primary electrons per pixel (epx) and the local BSE yield (η):

$$M ( {x}_{i} , OV ) = epx \times η ( {x}_{i} , OV )$$

and Q can be expressed as:

$$Q = {\frac{1}{epx} [ {\sum }_{i = 1}^{{N}_{p i x e l s}} \frac{1}{η ( {x}_{i} , OV )} {( \frac{\partial η}{\partial OV} ( {x}_{i} , OV ) )}^{2} ]}^{- 1}$$

The standard deviation is the square root of Q shown as:

$$σ = {\frac{1}{\sqrt{epx}} [ {\sum }_{i = 1}^{{N}_{pixels}} \frac{1}{η ( {x}_{i} , OV )} {( \frac{\partial η}{\partial OV} ( {x}_{i} , OV ) )}^{2} ]}^{- 1 / 2}$$

In some embodiments, the above formulas can be used to correlate the number of primary electrons per pixel (epx), the signal (the summation of N pixels), to the overlay precision (σ). In some embodiments, based on the number of primary electrons per pixel (epx), an acquisition time can be obtained.

Reference is now made to FIG. 5A, which is a schematic diagram illustrating a cross-sectional view of a wafer 500 including buried gratings 508 (or buried lines) in an underlying layer 504, consistent with some embodiments of the present disclosure. In some embodiments, wafer 500 includes a substrate 502 (e.g., a Si substrate), an underlying oxide layer 504 (e.g., a SiO₂ layer) formed on substrate 502, and a layer 506 (e.g., a PMMA layer) disposed on oxide layer 504. In some embodiments, a plurality of buried features, such as buried gratings 508, are included in wafer 500. For example, the buried features may have dimensions including a pitch (P) corresponding to a spacing between adjacent lines, a width (W) of a respective feature (e.g., half of the pitch value), and a height (H) of the respective feature. In some embodiments, η₁ and η₂ correspond to yield values measured at different locations on the wafer. For example, as shown in FIG. 5A, η₁ corresponds to the yield value of BSEs generated from the primary electron beam 202 injected through a buried grating 508, and η₂ corresponds to the yield value of BSEs generated from the primary electron beam 202 not passing through a buried grating 508. As such, data points including signals and noise can be obtained from a plurality of measurements at different locations on wafer 502 for fitting and generating the model used for optimizing the overlay measurement (e.g., models 307 of FIG. 3, or models 440 of FIG. 4) as discussed herein.

In some embodiments, a model may be related to the contrast to noise ratio in models 440 of FIG. 4, and generated based on the BSEs signal provided by buried features, such as buried grating 508 as shown in FIG. 5A. In some embodiments, the model may be an analytical model or a Monte Carlo model. The analytical model based on the backscattered electron yields (η) related to the contrast to noise ratio may be more efficient and less computationally demanding than traditional Monte Carlo simulations. After obtaining the model, the beam landing energy can be optimized for improving the contrast to noise ratio, as a higher contrast to noise ratio may lead to a shorter acquisition time.

In some embodiments, the model may be related to the acquisition time in model 440 of FIG. 4, and generated based on the error between the measured positioning of the buried gratings 508 and the reference positioning of the buried gratings. In some embodiments, given certain feature dimensions (e.g., P, W, or H in FIG. 5A), the beam current can be determined by optimization based on the trade-off between a high current leading to more signal per time unit, and a larger spot size which reduces the contrast to noise ratio (with longer acquisition time).

In some embodiments, a model used for optimizing SEM parameters of overlay measurements of buried gratings/lines features as shown in FIG. 5A can be obtained as below, with the assumption that a detector efficiency (η_{det}) is independent of beam current and energy, and the spot size depends on the beam current:

$$t = \frac{e}{{I}_{opt}} {( \frac{P}{π \cdot st d ( x )} )}^{2} \frac{{e}^{{( 2 π \frac{{σ}_{spot} ( {I}_{opt} )}{P} )}^{2}}}{{η}_{det}} \frac{{η}_{1} + {η}_{2}}{{( {η}_{1} - {η}_{2} )}^{2}}$$

where t is the acquisition time (or probing time) corresponding to time needed to acquire enough signal of grating periods over multiple lines; Iₒₚₜ≈0.090958 P^{1.84229} is the optimal beam current with a unit in nA and a maximum value of 100 nA; P is the pitch of the buried gratings as shown in FIG. 5A and with a unit in nm; std(x) is the standard deviation, e.g., corresponding to a certain overlay precision, that equals to 0.1/3 (in nm), which corresponds to the overlay precision error; η_{det} is detector efficiency that equals to 0.51; σₛₚₒₜ(Iₒₚₜ)≈0.5612 I^{0.54280} with the standard deviation of spot size σₛₚₒₜ in nm, and the optimal beam current Iₒₚₜ in nA; η₁ and η₂ are yield values based on the SEM signal; and the scan lines are assumed to be independent from each other. In some embodiments,

$$\frac{{e}^{{( 2 π \frac{{σ}_{spot} ( {I}_{opt} )}{P} )}^{2}}}{{η}_{det}}$$

is a throughput reduction factor due to detector efficiency and finite spot size. In some embodiments,

$$\frac{{η}_{1} + {η}_{2}}{{( {η}_{1} - {η}_{2} )}^{2}}$$

is a noise over contrast metric, and can be sued for determining the optimized landing energy.

FIG. 5B is a schematic diagram illustrating a cross-sectional view showing electron beams with different landing energies passing through features on a wafer, consistent with some embodiments of the present disclosure. In some embodiments, an electron beam, e.g., electron beam 552, 554, or 556, widens as it penetrates the wafer stack. Patterns (e.g., features, lines, etc.) at a certain depth level receive a wider beam with lower landing energies, such as beam 552 in FIG. 5B, and a narrower beam with higher landing energies, such as beam 556 in FIG. 5B. As the electron beam scans over the patterns, the beam width may be narrow enough (e.g., with the landing energy high enough) to scan all the patterns individually with sufficient precision. As such, putting the beam above the pattern or between the pattern will result in large difference in BSE yield, hence a significant contrast to noise ratio (e.g., the contrast).

In some embodiments, a lower landing energy will result in a wider beam, e.g., beam 552, which even when placed above the space between features, the detector may receive BSE's resulting from scattering back from the adjacent line features 508. In some embodiments, when placing the beam above a line feature, the BSE's also includes those scattered from space between the features. As such, low landing energy beam 552 results in an overall decrease in contrast.

In some embodiments, electron beam 556 with landing energy too high may result in a narrower beam as shown in FIG. 5B, which may have electrons penetrating through the patterns more easily, which may also reduce contrast. As such, it is desirable to have an optimal landing energy to have improved contrast and short acquisition time in inspecting the features in the wafer stack.

In some embodiments, finding the optimal landing energy may be performed by acquiring images obtained from electron beams with different landing energies, and selecting the one that gives the best contrast to noise ratio. The model discussed herein can be used for estimating optimal landing energies that are more likely to result in better contrast.

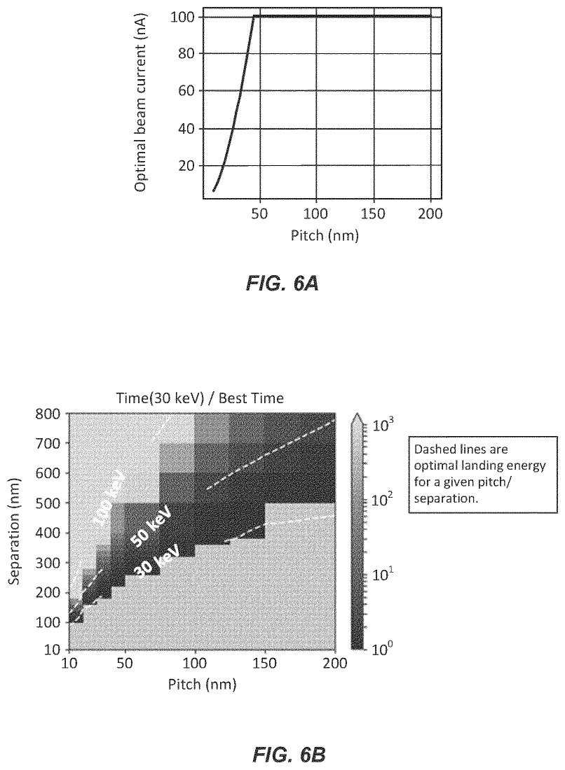

Using the models discussed herein, the throughput of high-voltage SEM can be maximized for a given wafer stack (e.g., with certain geometry and materials) and certain SEM hardware parameters (e.g., beam spot size, detector efficiency). FIG. 6A is a schematic diagram illustrating an example showing the relationships between optimal beam currents (nA) and certain pitch values (nm) based on the model for the buried gratings in FIG. 5, consistent with some embodiments of the present disclosure. FIG. 6B is a schematic diagram illustrating an example of a throughput gain that can be achieved by selecting the optimal landing energy for a certain wafer stack, consistent with some embodiments of the present disclosure. For example, as shown in FIG. 5, if the pitch P in the stack is 50 nm and a buried grating is at 350 nm below the surface (e.g., the separation), as shown in FIG. 6B, the probing time t at 30 keV is about 10 times slower than the probing time t at the optimal landing energy of about 50 keV. In some embodiments, the model can have various suitable formats corresponding to other types of buried features.

In some embodiments, the system discussed herein, such as system 300, system 100, or apparatus 104, can build a material library with e-beam properties (e.g., backward scattering efficiency) as functions of e-beam parameters (e.g., landing energy, sensor parameters). In some embodiments, the system can calibrate a universal heuristic or machine learning model used for e-beam image prediction. The system can use the calibrated model to predict e-beam images for a given wafer topography. The system can also recommend regions of optimal parameters for certain applications, such as efficient overlay measurements.

In some embodiments, a first principle model Y may be used to predict yield for a location in the wafer based on the inspection FOV:

η(x,y)=Y (wafer stack (including materials), landing energy, sensor and other e-beam parameters)

In some embodiments, the model Y can further be formulated in the following form with two functions including ƒ( ) and g( )

η(x,y)=ƒ(wafer stack (including materials), g(material, landing energy, sensor and other e-beam parameters))

where g( ) is related to both material properties and e-beam properties, analogous to the optical properties n and k as functions of wavelength. In some embodiments, function g( ) is stack-independent. In some embodiments, function g( ) is more computation intensive than function ƒ( ) In some embodiments, function g( ) may be pre-calculated and stored in the material library. During overlay inspection, function g( ) can be retrieved from the material library, so that the turn-around-time for contrast prediction may be related to the calculation of function ƒ( ) associated with the wafer stack under inspection. In some embodiments, the functions ƒ( ) and g( ) may be heuristic, trained by real image captured, or via first principle simulations. In some embodiments, the wafer stack parameters for function ƒ( ) may include one or more parameters as discussed for wafer stack parameters 410. In some embodiments, the e-beam parameters for function g( ) include one or more e-beam characteristics discussed herein, such as SEM parameters 420, Optimization target 430, or any other suitable e-beam parameters associated with as system 300, system 100, or apparatus 104.

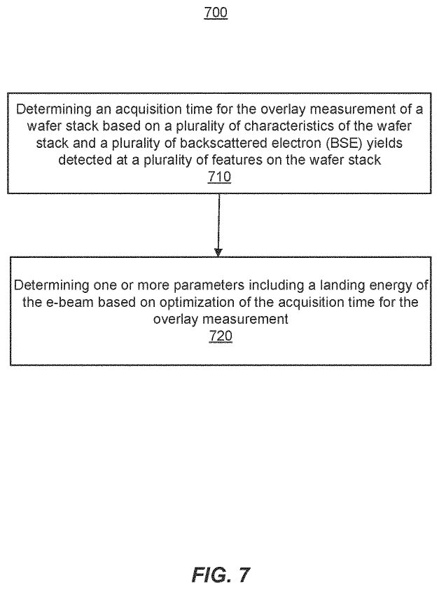

FIG. 7 is a process flowchart representing an example method 700 for determining one or more parameters used by an e-beam for an overlay measurement, such as optimized SEM parameters, in accordance with some embodiments of the present disclosure. In some embodiments, one or more steps are performed by one or more components of system 300 in FIG. 3, controller 109, system 199, or apparatus 104 in FIG. 2, or system 100 in FIG. 1.

As shown in FIG. 7, in step 710, an acquisition time is determined for the overlay measurement of a wafer stack. In some embodiments, the acquisition time is expressed using models 307 of FIG. 3, or models 440 of FIG. 4. In some embodiments, the acquisition time is determined based on a plurality of characteristics of the wafer stack 410 such as a density or an atomic number of materials in the wafer stack. In some embodiments, the acquisition time is determined based on a plurality of characteristics of the wafer stack 410 including geometries (e.g., gratings) or dimensions (e.g., pitch) of a plurality of features formed on the wafer stack. For example, as shown in FIG. 5, the plurality of features include a plurality of buried line features. In some embodiments, the acquisition time is also determined based on a plurality of BSE yields detected at the plurality of features on the wafer stack. The BSE yields may be obtained as a function of landing energy.

In some embodiments, the acquisition time is further determined based on adjustment of one or more SEM hardware parameters 420 corresponding to a relationship between spot size and beam current, or a relationship between spot size and beam landing energy. In some embodiments, adjustment of SEM hardware parameters 420 may also correspond to a relationship between detector efficiency and beam current, or a relationship between detector efficiency and beam landing energy. In some embodiments, the acquisition time is also determined based on an overlay specification, such as an overlay precision.

In step 720, the one or more parameters including an optimal landing energy of the e-beam are determined based on optimization of the acquisition time for the overlay measurement (e.g., FIG. 6B). In some embodiments, the one or more parameters including an optimal beam current of the e-beam can also be determined based on optimization of the acquisition time for the overlay measurement.

A non-transitory computer readable medium may be provided that stores instructions for a processor of a controller (e.g., controller 109 of FIGS. 1-2) to carry out, among other things, image inspection, image acquisition, stage positioning, beam focusing, electric field adjustment, beam bending, condenser lens adjusting, activating charged-particle source, beam deflecting, and for processing reference data such as described above regarding method 700. Common forms of non-transitory media include, for example, a floppy disk, a flexible disk, hard disk, solid state drive, magnetic tape, or any other magnetic data storage medium, a Compact Disc Read Only Memory (CD-ROM), any other optical data storage medium, any physical medium with patterns of holes, a Random Access Memory (RAM), a Programmable Read Only Memory (PROM), and Erasable Programmable Read Only Memory (EPROM), a FLASH-EPROM or any other flash memory, Non-Volatile Random Access Memory (NVRAM), a cache, a register, any other memory chip or cartridge, and networked versions of the same.

The embodiments may further be described using the following clauses:
1. A system for determining one or more parameters used by an e-beam for an overlay measurement, the system comprising:
a controller including circuitry configured to cause the system to perform:
determining an acquisition time for the overlay measurement of a wafer stack based on a plurality of characteristics of the wafer stack and a plurality of backscattered electron (BSE) yields detected at a plurality of features on the wafer stack; and
determining the one or more parameters including a landing energy of the e-beam based on optimization of the acquisition time for the overlay measurement.
2. The system of clause 1, wherein the plurality of characteristics of the wafer stack comprise a density or an atomic number of materials in the wafer stack.
3. The system of any one of clauses 1-2, wherein the plurality of characteristics of the wafer stack comprise geometries or dimensions of the plurality of features on the wafer stack.
4. The system of clause 3, wherein the plurality of features include a set of buried line features, and wherein the dimensions of the buried line features include a pitch.
5. The system of any one of clauses 1-4, wherein the acquisition time is further determined based on one or more hardware parameters related to a spot size of the e-beam.
6. The system of any one of clauses 1-5, wherein the acquisition time is further determined based on one or more hardware parameters related to a detector efficiency.
7. The system of any one of clauses 1-6, wherein the acquisition time is further determined based on an overlay specification.
8. The system of any one of clauses 1-7, wherein the controller includes circuitry configured to cause the system to further perform:
determining the one or more parameters including a beam current of the e-beam based on optimization of the acquisition time for the overlay measurement.
9. The system of any one of clauses 1-8, wherein determining the acquisition time for the overlay measurement further comprises:
fitting signal measurements of the plurality of features on the wafer stack using a least squares regression analysis; and
optimizing the acquisition time for the overlay measurement based on a standard deviation.
10. A non-transitory computer readable medium that stores a set of instructions that is executable by at least one processor of a system to cause the system to perform a method of determining one or more parameters used by an e-beam for an overlay measurement, the method comprising:
determining an acquisition time for the overlay measurement of a wafer stack based on a plurality of characteristics of the wafer stack and a plurality of backscattered electron (BSE) yields detected at a plurality of features on the wafer stack; and
determining the one or more parameters including a landing energy of the e-beam based on optimization of the acquisition time for the overlay measurement.
11. The non-transitory computer readable medium of clause 10, wherein the plurality of characteristics of the wafer stack comprise a density or an atomic number of materials in the wafer stack.
12. The non-transitory computer readable medium of any one of clauses 10-11, wherein the plurality of characteristics of the wafer stack comprise geometries or dimensions of the plurality of features on the wafer stack.
13. The non-transitory computer readable medium of clause 12, wherein the plurality of features include a set of buried line features, and wherein the dimensions of the buried line features include a pitch.
14. The non-transitory computer readable medium of any one of clauses 10-13, wherein the acquisition time is further determined based on one or more hardware parameters related to a spot size of the e-beam.
15. The non-transitory computer readable medium of any one of clauses 10-14, wherein the acquisition time is further determined based on one or more hardware parameters related to a detector efficiency.
16. The non-transitory computer readable medium of any one of clauses 10-15, wherein the acquisition time is further determined based on an overlay specification.
17. The non-transitory computer readable medium of any one of clauses 10-16, wherein the controller includes circuitry configured to cause the system to further perform:
determining the one or more parameters including a beam current of the e-beam based on optimization of the acquisition time for the overlay measurement.
18. The non-transitory computer readable medium of any one of clauses 10-17, wherein determining the acquisition time for the overlay measurement further comprises:
fitting signal measurements of the plurality of features on the wafer stack using a least squares regression analysis; and
optimizing the acquisition time for the overlay measurement based on a standard deviation.
19. A method of determining one or more parameters used by an e-beam for an overlay measurement, the method comprising:
determining an acquisition time for the overlay measurement of a wafer stack based on a plurality of characteristics of the wafer stack and a plurality of backscattered electron (BSE) yields detected at a plurality of features on the wafer stack; and
determining the one or more parameters including a landing energy of the e-beam based on optimization of the acquisition time for the overlay measurement.
20. The method of clause 19, wherein the plurality of characteristics of the wafer stack comprise a density or an atomic number of materials in the wafer stack.
21. The method of any one of clauses 19-21, wherein the plurality of characteristics of the wafer stack comprise geometries or dimensions of the plurality of features on the wafer stack.
22. The method of clause 21, wherein the plurality of features include a set of buried line features, and wherein the dimensions of the buried line features include a pitch.
23. The method of any one of clauses 19-22, wherein the acquisition time is further determined based on one or more hardware parameters related to a spot size of the e-beam.
24. The method of any one of clauses 19-23, wherein the acquisition time is further determined based on one or more hardware parameters related to a detector efficiency.
25. The method of any one of clauses 19-24, wherein the acquisition time is further determined based on an overlay specification.
26. The method of any one of clauses 19-25, further comprising:
determining the one or more parameters including a beam current of the e-beam based on optimization of the acquisition time for the overlay measurement.
27. The method of any one of clauses 19-26, wherein determining the acquisition time for the overlay measurement further comprises:
fitting signal measurements of the plurality of features on the wafer stack using a least squares regression analysis; and
optimizing the acquisition time for the overlay measurement based on a standard deviation.
28. A system for determining one or more parameters used by an e-beam for an overlay measurement, comprising:
a controller including circuitry configured to cause the system to perform:
determining a plurality of backscattered electron (BSE) yields detected at a plurality of features on a wafer stack, wherein the BSE yields are determined by a first group of wafer stack parameters of the wafer stack and a second group of material properties and e-beam parameters;
optimizing an acquisition time for the overlay measurement of the wafer stack, the acquisition time determined based on the first group of wafer stack parameters and the plurality of backscattered electron (BSE) yields; and
determining the one or more parameters including a landing energy of the e-beam based on the optimized acquisition time for the overlay measurement.
29. The system of clause 28, wherein the second group of material properties and e-beam parameters are pre-determined by a heuristic model and prestored in a material library for retrieval during the overlay measurement.
30. The system of any one of clauses 28-29, wherein the second group of material properties and e-beam parameters are pre-determined by a machine learning model trained based on e-beam images obtained by corresponding e-beam parameters and material properties, the second group of material properties and e-beam parameters prestored in a material library for retrieval during the overlay measurement.
31. The system of any one of clauses 28-30, wherein the second group of material properties and e-beam parameters comprise landing energy, a spot size of the e-beam, or a detector efficiency.
32. The system of any one of clauses 28-31, wherein the first group of wafer stack parameters comprise a density or an atomic number of materials in the wafer stack, or geometries or dimensions of the plurality of features on the wafer stack.
33. The system of clause 32, wherein the plurality of features include a set of buried line features, and wherein the dimensions of the buried line features include a pitch.
34. A non-transitory computer readable medium that stores a set of instructions that is executable by at least one processor of a system to cause the system to perform a method of determining one or more parameters used by an e-beam for an overlay measurement, the method comprising:
determining a plurality of backscattered electron (BSE) yields detected at a plurality of features on a wafer stack, wherein the BSE yields are determined by a first group of wafer stack parameters of the wafer stack and a second group of material properties and e-beam parameters;
optimizing an acquisition time for the overlay measurement of the wafer stack, the acquisition time determined based on the first group of wafer stack parameters and the plurality of backscattered electron (BSE) yields; and
determining the one or more parameters including a landing energy of the e-beam based on the optimized acquisition time for the overlay measurement.
35. The non-transitory computer readable medium of clause 34, wherein the second group of material properties and e-beam parameters are pre-determined by a heuristic model and prestored in a material library for retrieval during the overlay measurement.
36. The non-transitory computer readable medium of any one of clauses 34-35, wherein the second group of material properties and e-beam parameters are pre-determined by a machine learning model trained based on e-beam images obtained by corresponding e-beam parameters and material properties, the second group of material properties and e-beam parameters prestored in a material library for retrieval during the overlay measurement.
37. The non-transitory computer readable medium of any one of clauses 34-36, wherein the second group of material properties and e-beam parameters comprise landing energy, a spot size of the e-beam, or a detector efficiency.
38. The non-transitory computer readable medium of any one of clauses 34-37, wherein the first group of wafer stack parameters comprise a density or an atomic number of materials in the wafer stack, or geometries or dimensions of the plurality of features on the wafer stack.
39. The non-transitory computer readable medium of clause 38, wherein the plurality of features include a set of buried line features, and wherein the dimensions of the buried line features include a pitch.
40. A method of determining one or more parameters used by an e-beam for an overlay measurement, the method comprising:
determining a plurality of backscattered electron (BSE) yields detected at a plurality of features on a wafer stack, wherein the BSE yields are determined by a first group of wafer stack parameters of the wafer stack and a second group of material properties and e-beam parameters;
optimizing an acquisition time for the overlay measurement of the wafer stack, the acquisition time determined based on the first group of wafer stack parameters and the plurality of backscattered electron (BSE) yields; and
determining the one or more parameters including a landing energy of the e-beam based on the optimized acquisition time for the overlay measurement.
41. The method of clause 40, wherein the second group of material properties and e-beam parameters are pre-determined by a heuristic model and prestored in a material library for retrieval during the overlay measurement.
42. The method of any one of clauses 40-41, wherein the second group of material properties and e-beam parameters are pre-determined by a machine learning model trained based on e-beam images obtained by corresponding e-beam parameters and material properties, the second group of material properties and e-beam parameters prestored in a material library for retrieval during the overlay measurement.
43. The method of any one of clauses 40-42, wherein the second group of material properties and e-beam parameters comprise landing energy, a spot size of the e-beam, or a detector efficiency.
44. The method of any one of clauses 40-43, wherein the first group of wafer stack parameters comprise a density or an atomic number of materials in the wafer stack, or geometries or dimensions of the plurality of features on the wafer stack.
45. The method of clause 44, wherein the plurality of features include a set of buried line features, and wherein the dimensions of the buried line features include a pitch.

It will be appreciated that the embodiments of the present disclosure are not limited to the exact construction that has been described above and illustrated in the accompanying drawings, and that various modifications and changes may be made without departing from the scope thereof. The present disclosure has been described in connection with various embodiments, other embodiments of the invention will be apparent to those skilled in the art from consideration of the specification and practice of the invention disclosed herein. It is intended that the specification and examples be considered as exemplary only, with a true scope and spirit of the invention being indicated by the following claims.

The descriptions above are intended to be illustrative, not limiting. Thus, it will be apparent to one skilled in the art that modifications may be made as described without departing from the scope of the claims set out below.

1. A system for determining one or more parameters used by an e-beam for an overlay measurement, the system comprising:
a controller including circuitry configured to cause the system to perform:
determining an acquisition time for the overlay measurement of a wafer stack based on a plurality of characteristics of the wafer stack and a plurality of backscattered electron (BSE) yields detected at a plurality of features on the wafer stack; and
determining the one or more parameters including a landing energy of the e-beam based on optimization of the acquisition time for the overlay measurement.

2. The system of claim 1, wherein the plurality of characteristics of the wafer stack comprise a density or an atomic number of materials in the wafer stack.

3. The system of claim 1, wherein the plurality of characteristics of the wafer stack comprise geometries or dimensions of the plurality of features on the wafer stack.

4. The system of claim 3, wherein the plurality of features include a set of buried line features, and wherein the dimensions of the buried line features include a pitch.

5. The system of claim 1, wherein the acquisition time is further determined based on one or more hardware parameters related to a spot size of the e-beam.

6. The system of claim 1, wherein the acquisition time is further determined based on one or more hardware parameters related to a detector efficiency.

7. The system of claim 1, wherein the acquisition time is further determined based on an overlay specification.

8. The system of claim 1, wherein the controller includes circuitry configured to cause the system to further perform:
determining the one or more parameters including a beam current of the e-beam based on optimization of the acquisition time for the overlay measurement.

9. The system of claim 1, wherein determining the acquisition time for the overlay measurement further comprises:
fitting signal measurements of the plurality of features on the wafer stack using a least squares regression analysis; and
optimizing the acquisition time for the overlay measurement based on a standard deviation.

10. A non-transitory computer readable medium that stores a set of instructions that is executable by at least one processor of a system to cause the system to perform a method of determining one or more parameters used by an e-beam for an overlay measurement, the method comprising:
determining an acquisition time for the overlay measurement of a wafer stack based on a plurality of characteristics of the wafer stack and a plurality of backscattered electron (BSE) yields detected at a plurality of features on the wafer stack; and
determining the one or more parameters including a landing energy of the e-beam based on optimization of the acquisition time for the overlay measurement.

11. The non-transitory computer readable medium of claim 10, wherein the plurality of characteristics of the wafer stack comprise a density or an atomic number of materials in the wafer stack.

12. The non-transitory computer readable medium of claim 10, wherein the plurality of characteristics of the wafer stack comprise geometries or dimensions of the plurality of features on the wafer stack.

13. The non-transitory computer readable medium of claim 12, wherein the plurality of features include a set of buried line features, and wherein the dimensions of the buried line features include a pitch.

14. The non-transitory computer readable medium of claim 10, wherein the acquisition time is further determined based on one or more hardware parameters related to a spot size of the e-beam.

15. The non-transitory computer readable medium of claim 10, wherein the acquisition time is further determined based on one or more hardware parameters related to a detector efficiency.

16. A system for determining one or more parameters used by an e-beam for an overlay measurement, comprising:
a controller including circuitry configured to cause the system to perform:
determining a plurality of backscattered electron (BSE) yields detected at a plurality of features on a wafer stack, wherein the BSE yields are determined by a first group of wafer stack parameters of the wafer stack and a second group of material properties and e-beam parameters;
optimizing an acquisition time for the overlay measurement of the wafer stack, the acquisition time determined based on the first group of wafer stack parameters and the plurality of backscattered electron (BSE) yields; and
determining the one or more parameters including a landing energy of the e-beam based on the optimized acquisition time for the overlay measurement.

17. The system of claim 16, wherein the second group of material properties and e-beam parameters are pre-determined by a heuristic model and prestored in a material library for retrieval during the overlay measurement.

18. The system of claim 16, wherein the second group of material properties and e-beam parameters are pre-determined by a machine learning model trained based on e-beam images obtained by corresponding e-beam parameters and material properties, the second group of material properties and e-beam parameters prestored in a material library for retrieval during the overlay measurement.

19. The system of claim 16, wherein the second group of material properties and e-beam parameters comprise landing energy, a spot size of the e-beam, or a detector efficiency.

20. The system of claim 16, wherein the first group of wafer stack parameters comprise a density or an atomic number of materials in the wafer stack, or geometries or dimensions of the plurality of features on the wafer stack.
